(19) United States
(12) Patent Application Publication
(10) Pub. No.: US 2026/0369528 A1
(43) Pub. Date: Nov. 19, 2026

(54) MATCHLESS PLASMA SOURCE AND OPERATING METHOD THEREFOR

(71) Applicant: RFPT Co., LTD., Anyang-si Gyeonggi-do (KR)

(72) Inventors: Hongki KIM, Anyang-si Gyeonggi-do (KR); Sung Kyu SHIN, Anyang-si Gyeonggi-do (KR); Dong Heon LEE, Anyang-si Gyeonggi-do (KR)

(21) Appl. No.: 19/143,856

(22) PCT Filed: Dec. 26, 2023
(86) PCT No.: PCT/KR2023/021548

§ 371 Date: Mar. 27, 2026

(30) Foreign Application Priority Data
Dec. 27, 2022 (KR) 10-2022-0185906
Dec. 22, 2023 (KR) 10-2023-0189939

(51) Int. Cl. H01J 37/32

(52) U.S. Cl. CPC H01J 37/32174

(57) ABSTRACT

Disclosed are a matchless plasma source and an operating method therefor. A matchless plasma source according to an embodiment may comprise: a detector connected to a reactive circuit to detect an RF voltage or current at a reactive circuit end; the reactive circuit arranged at an output end of the matchless plasma source; and a controller configured to calculate and control a tuning frequency, a pulse width, and a DC voltage of the RF power provided by the matchless plasma source on the basis of a reactance of the reactive circuit and the RF voltage or current detected by the detector while being connected to the reactive circuit and the detector.

### TECHNOLOGY FIELD

A plasma source used in a plasma processing apparatus and an operating method thereof are disclosed.

### BACKGROUND

In a semiconductor processing process of etching, depositing, and cleaning a pure semiconductor wafer, a plasma processing apparatus is used as a core equipment.

Generally, a plasma processing apparatus includes a plasma chamber, a radio frequency power generator (RF generator) that generates radio frequency power, and an impedance matcher that minimizes power loss of the plasma chamber by matching an output impedance of the radio frequency power generator with an impedance of the plasma chamber for maximum power supply.

Conventionally, a structure in which a radio frequency power generator, an impedance matcher, and a plasma chamber are physically separated and connected by a coaxial cable or the like to constitute a plasma processing apparatus is common, but the structure may cause problems such as instability due to mismatch, transmission loss, and the like.

Thus, in order to compensate for the problems described, an integrated structure in which a radio frequency power generator, an impedance matcher, and a plasma chamber are integrated has been proposed. The integrated structure is disclosed in Korean Patent Application Publication Nos. KR10-2020-0059310, KR10-2020-0121909, and KR10-2021-0034059.

The integrated structure may achieve a matching effect by cancelling out the jX component, which is an imaginary part in the R+jX, which is an equivalent circuit impedance of the plasma chamber, through the impedance adjustment of the reactive circuit and the RF frequency adjustment of the signal generator, leaving only the R component, which is a real part to be in a minimum impedance state, and then making the phases of the voltage and the current in an in-phase state to transmit the maximum power to the plasma chamber.

At this time, the magnitude of the RF output may be adjusted by the voltage of an arbitrary waveform generator, so that the integrated structure generates and provides an arbitrary output waveform through the arbitrary waveform generator.

That is, the integrated structure may replace the role of the conventional impedance matcher with the reactive circuit and voltage adjustment method to simplify and miniaturize the apparatus.

However, the integrated structure has disadvantages in that it uses an arbitrary waveform generator provided separately from the RF signal generator that generates the RF power to rapidly change the voltage of a DC power supply unit into the amplitude of the radio frequency output power, resulting in slow response speed, low power efficiency, high cost, and inability to maximize miniaturization

Therefore, there is a need to propose a technique for solving the disadvantages of the integral structure.

### DETAILED DESCRIPTION OF THE INVENTION

### Technical Problem

One embodiment proposes a matchless plasma source that controls the RF signal generator to generate RF power having a controlled tuning frequency and pulse width at the RF signal generator, while omitting an arbitrary waveform generator, in order to improve response speed and power efficiency, reduce cost, and maximize miniaturization.

However, the technical problems to be solved by the present invention are not limited to the above problems, and may be variously extended without departing from the technical spirit and scope of the present invention.

### Solution to Problem

According to an embodiment, matchless plasma source providing RF power of a first frequency to an electrode of a plasma chamber while being connected to the plasma chamber, the matchless plasma source may include a detector connected to a reactive circuit to detect an RF voltage or current at a reactive circuit end; the reactive circuit arranged at an output end of the matchless plasma source; and a controller configured to calculate and control a tuning frequency, a pulse width, and a DC voltage of the RF power provided by the matchless plasma source on the basis of a reactance of the reactive circuit and the RF voltage or current detected by the detector while being connected to the reactive circuit and the detector.

According to one aspect, the controller may be configured to control an RF signal generator further included in the matchless plasma source such that the RF signal generator generates the RF power having the controlled tuning frequency and pulse width.

According to another aspect, the controller may be configured to control a reactance of the reactive circuit such that reactance components of each of the reactive circuit and the plasma chamber are series-resonant or parallel-resonant at the first frequency to serve as a band pass filter (BPF).

According to another aspect, the matchless plasma source may further include a low pass filter (LPF) or a band pass filter (BPF) arranged at an output end of the reactive circuit.

According to another aspect, the matchless plasma source may further include an RF signal generator configured to generate the RF power; a frequency controller configured to adjust a frequency of the RF power under control of the controller; a pulse width controller configured to adjust a pulse width of the RF power under control of the controller; a DC power supply configured to supply power to the matchless plasma source; a gate driver connected to the RF signal generator; and a power amplifier connected to the gate driver and configured to amplify the RF power.

According to another aspect, the controller may be configured to control a DC voltage output from the DC power supply unit.

According to another aspect, an output end of the power amplifier may include a half-bridge transistor circuit or a full-bridge transistor circuit.

According to another aspect, an output end of the power amplifier may include a transistor circuit configured in a SiC or GaN scheme.

According to another aspect, an output end of the power amplifier may include a transistor circuit configured in a Class E series or a class C-E scheme.

According to another aspect, the DC power supply unit configured to supply power to the matchless plasma source may have a variable voltage output characteristic when the output end of the power amplifier includes the transistor circuit configured in the Class E series or Class C-E scheme.

According to an embodiment, a method of operating a matchless plasma source including a reactive circuit arranged at an output end; a detector connected to a front end or a rear end of the reactive circuit; and a controller connected to the reactive circuit and the detector, in order to provide RF power of a first frequency to an electrode of a plasma chamber while being connected to the plasma chamber, may include: detecting, by the detector, an RF voltage or current at the reactive circuit end; and calculating and controlling, by the controller, a tuning frequency, a pulse width, and a DC voltage of the RF power provided by the matchless plasma source on the basis of a reactance of the reactive circuit and the RF voltage or current detected by the detector.

According to one aspect, the controlling may include controlling an RF signal generator further included in the matchless plasma source such that the RF signal generator generates the RF power having the controlled tuning frequency and pulse width.

According to another aspect, the controlling further may include controlling a reactance of the reactive circuit such that reactance components of each of the reactive circuit and the plasma chamber are in series-resonant or parallel-resonant at the first frequency to serve as a band pass filter (BPF).

### Effects of Invention

One embodiment may achieve the technical effect of improving response speed and power efficiency, reducing cost, and maximizing miniaturization by proposing a matchless plasma source that controls the RF signal generator to generate RF power having the controlled tuning frequency and pulse width at the RF signal generator, while omitting an arbitrary waveform generator.

However, the effects of the present invention are not limited to the above effects, and may be variously extended without departing from the technical spirit and scope of the present invention.

### BRIEF DESCRIPTION OF THE DRAWINGS

FIG. 1 to FIG. 4 are each a diagram for describing a conventional matchless plasma source.

FIG. 5 is a block diagram for illustrating the concept of a matchless plasma source according to an embodiment.

FIG. 6 is a diagram showing a matchless plasma source according to an embodiment.

FIG. 7 is a flow chart showing a method of operating a matchless plasma source according to an embodiment.

### BEST MODE FOR CARRYING OUT THE INVENTION

Hereinafter, embodiments of the present invention will be described in detail with reference to the accompanying drawings so that those of ordinary skill in the art to which the present invention pertains may easily carry out the invention. Since the description of the present invention is merely exemplary for structural or functional description, the scope of the present invention should not be construed as being limited by the embodiments described herein.

That is, the present invention may be variously modified and implemented in many different forms, so that the present invention is not limited to the embodiments described herein and therefore, it should be understood that the scope of the present invention includes equivalents that may realize the technical idea.

Meanwhile, the meaning of the terms described in the present invention should be understood as follows.

The terms “first,” “second,” and the like are intended to distinguish one component from another component, and the scope of rights should not be limited by these terms. For example, a first component may be termed a second component, and similarly, the second component may also be termed the first component.

When it is stated that one component is “connected” to another component, it should be understood that it may be directly connected to that other component, but there may be another component in between. On the other hand, when it is stated that one component is “directly connected” to another component, it should be understood that there is no other component in between. Meanwhile, other expressions describing the relationship between the components, i.e., “between” and “directly between” or “neighboring to” and “direct neighboring to”, etc., should be interpreted as well.

It is to be understood that the singular forms “a,” “an,” and “the” include plural referents unless the context clearly dictates otherwise, and that the terms such as “include” or “have” are intended to designate the presence of a feature, number, step, operation, component, part, or combination thereof that has been implemented, and do not preclude the presence or possibility of addition of one or more other features, numbers, steps, operations, components, parts, or combinations thereof.

For each step, identification signs (e.g., a, b, c, etc.) are used for convenience of description, and the identification signs do not describe the order of each of the steps, and each of the steps may occur differently from the specified order unless the context clearly describes a specific order. That is, each of the steps may occur in the same order as specified, may be performed substantially simultaneously, or may be performed in the reverse order.

Unless defined otherwise, all terms used herein have the same meaning as commonly understood by those of ordinary skill in the art to which the present invention pertains. Terms defined in commonly used dictionaries should be interpreted as being consistent with their meaning in the context of the relevant art and cannot be interpreted as having an ideal or excessively formal meaning unless expressly defined herein.

It is noted that the drawings are schematic and not drawn to scale. The relative dimensions and proportions of the portions in the drawings are shown exaggerated or reduced in size for clarity and convenience in the drawings and any dimensions are merely illustrative and not limiting. And for the same structures, elements, or parts shown in two or more drawings, the same reference numerals are used to indicate similar features.

The embodiment according to the invention specifically represents an ideal embodiment of the invention. As a result, various modifications of the illustration are envisaged. The embodiment is thus not limited to the specific form of the region shown, but also includes modifications of the form, for example by manufacture.

Hereinafter, a matchless plasma source and an operating method thereof will be described with reference to the accompanying drawings.

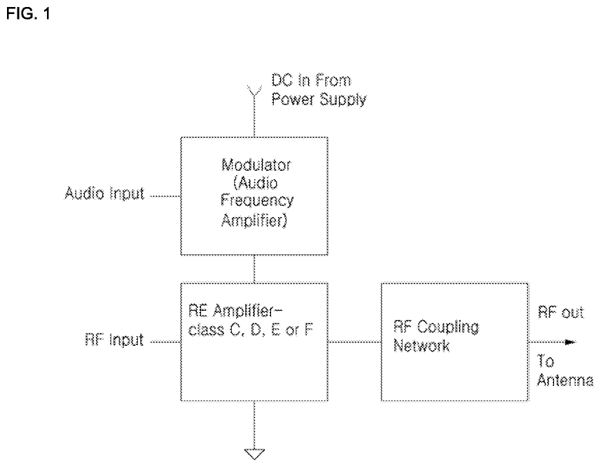

FIG. 1 to FIG. 4 are each a diagram for describing a conventional matchless plasma source.

Although a matchless plasma source according to an embodiment differs from a conventional matchless plasma source in terms of components and control methods, it has the same purpose, and therefore, an operating principle of the plasma source according to the embodiment will be described below based on the operating principle of the conventional matchless plasma source.

Since the conventional matchless plasma source implements an arbitrary waveform generator with an AM modulator coupled to and driven by a DC power supply unit, it rapidly changes the voltage of the DC power supply to the amplitude of the high-frequency output power, resulting in disadvantages such as slow response speed, low power efficiency, high cost, and the inability to maximize miniaturization.

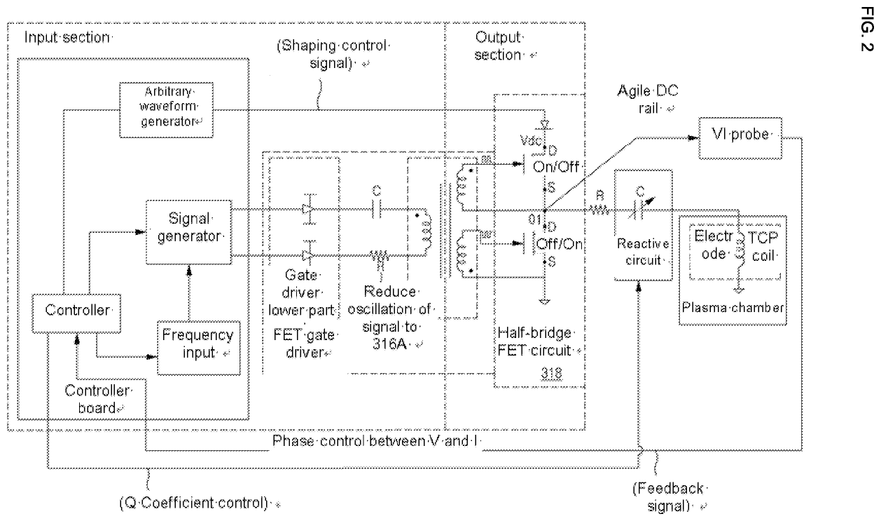

Referring to FIG. 2 to describe the conventional matchless plasma source, the conventional matchless plasma sources may change the magnitude of the RF power output by applying a shaping control signal generated by an arbitrary waveform generator on a controller board to an agile DC rail, which together are responsible for the DC power supply function of a half-bridge FET circuit, so as to offset the imaginary part of the TCP coil impedance of the plasma chamber with a reactive circuit.

The basic control concept of such conventional matchless plasma source is based on the theory that the phase of V/I input to a VI probe 324 is matched when the plasma chamber side and the reactive circuit 322A are conjugate-matched.

In other words, the conventional matchless plasma source is implemented such that the radio frequency power generator and the impedance matcher are integrated, simultaneously performing the respective functions of the radio frequency power generator and the impedance matcher

However, the matchless plasma source having the structure shown in FIG. 2 has the disadvantage that the voltage detection waveform of the V/I probe does not ideally come out and it is difficult to find an optimal matching point.

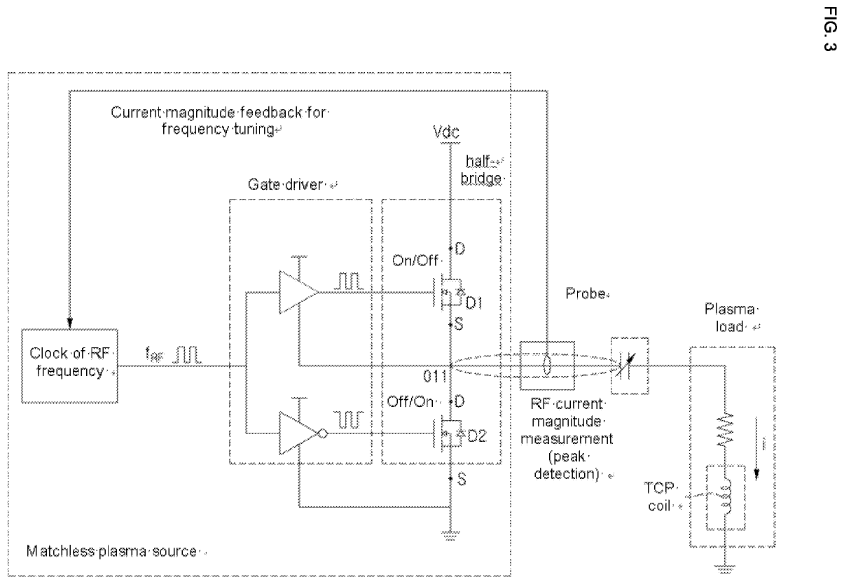

Accordingly, a structure as shown in FIG. 3 has been proposed to solve the disadvantage of the structure shown in FIG. 2.

The structure shown in FIG. 3 is a structure in which the V/I probe is replaced with the I probe, and the conventional matchless plasma source shown in FIG. 3 may perform matching by leaving only the R component, which is a real part to be in a minimum impedance state, when the TCP coil and the reactive circuit are conjugate-matched with each other, and then making the phases of the voltage and the current in an in-phase state to transmit the maximum power to the plasma chamber.

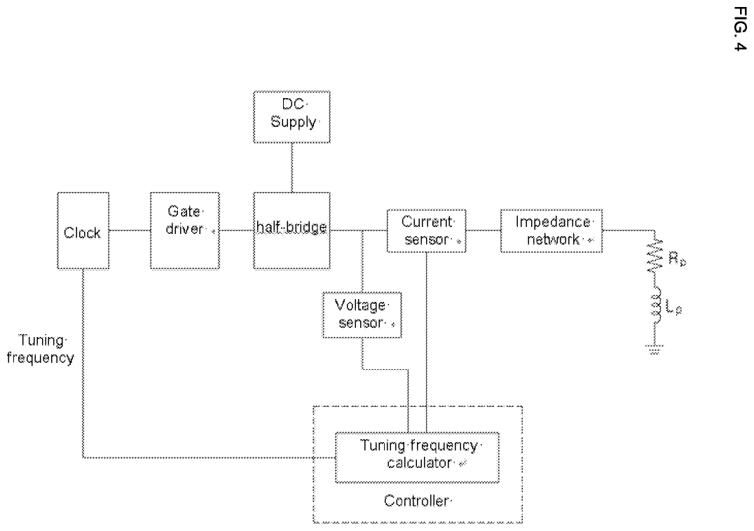

The conventional matchless plasma source having the structure shown in FIG. 4 also has a similar basic operating principle and configurations as the conventional matchless plasma sources shown in FIG. 2 and FIG. 3. The conventional matchless plasma source having the structure shown in FIG. 4 implements a matchless plasma system by selectively using the V/I probe or the I probe to adjust a frequency of a clock and a voltage of a DC supply.

The conventional matchless plasma source described above has the disadvantages of slow response speed, low power efficiency, high cost, and the inability to maximize miniaturization because it rapidly changes the voltage of the DC power supply unit to the amplitude of the radio frequency output power.

Accordingly, hereinafter, a matchless plasma source according to an embodiment of the present invention will be described, which applies a structure and method that controls an RF signal generator to generate RF power having a controlled tuning frequency and pulse width (or conduction angle) at the RF signal generator.

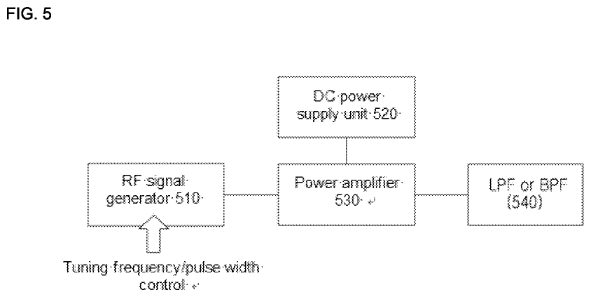

FIG. 5 is a block diagram for illustrating the concept of a matchless plasma source according to an embodiment.

Referring to FIG. 5, the matchless plasma source according to an embodiment may control the tuning frequency and pulse width of the RF power through a controller coupled to a RF signal generator 510 in a structure including the RF signal generator 510, a DC power supply unit 520, a power amplifier 530, and a low pass filter (LPF) or a band pass filter (BPF) 540, thereby achieving a technical effect of improving response speed and power efficiency, reducing cost, and maximizing miniaturization.

In this case, the low pass filter or the band pass filter 540 may be omitted according to an implementation example.

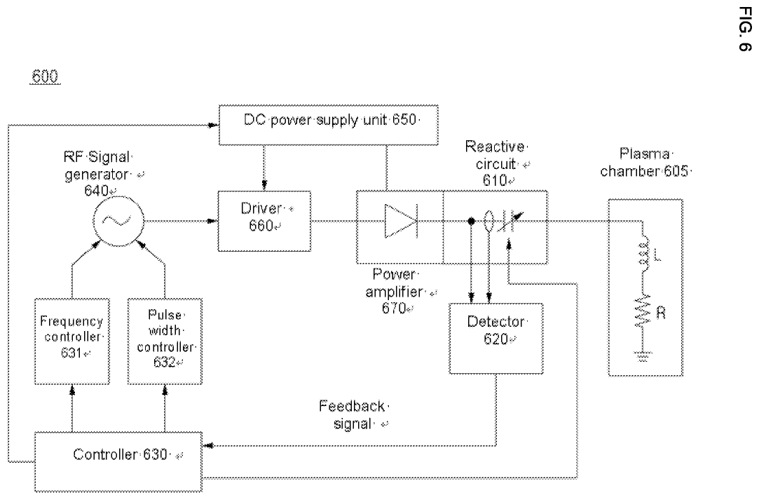

FIG. 6 is a diagram showing a matchless plasma source according to an embodiment.

Referring to FIG. 6, a matchless plasma source 600 according to an embodiment may include a reactive circuit 610 arranged at an output end of the matchless plasma source 600, a detector 620 connected to a front end or a rear end of the reactive circuit, and a controller 630 connected to the reactive circuit 610 and the detector 620, in order to provide RF power of a first frequency to an electrode of a plasma chamber 605 while being connected to the plasma chamber 605.

The detector 620 is a configuration that detects an RF voltage or current at the reactive circuit 610 end (at the output of the matchless plasma source 600, at the input or output of the reactive circuit 610) and transmits the detected RF voltage or current as a feedback signal to the controller 630, and it may be implemented, for example, as the V/I probe or the I probe.

The controller 630 may calculate and control the tuning frequency, pulse width, and DC voltage of the RF power provided by the matchless plasma source 600 based on a reactance of the reactive circuit 610, the RF voltage or current detected by the detector 620.

More specifically, the controller 630 may control an RF signal generator 640 further included in the matchless plasma source 600 such that the RF signal generator 640 generates the RF power having the controlled tuning frequency and pulse width (or conduction angle).

In addition, the controller 630 may control the output voltage of the DC power supply unit 650 (the DC voltage output from the DC power supply unit 650) further included in the matchless plasma source 600 to obtain better characteristics.

To this end, the matchless plasma source 600 may further include the RF signal generator 640 configured to generate RF power that is an RF signal in 400 kHz, 2 MHZ, 13.56 Mhz, 27 MHz, and 60 MHz bands; a frequency controller 631 configured to adjust the frequency of the RF power under the control of the controller 630; a pulse width controller 632 configured to adjust the pulse width (or conduction angle) of the RF power under the control of the controller 630; a DC power supply unit 650 configured to supply power to the matchless plasma source 600; a gate driver 660 connected to the RF signal generator 640; and a power amplifier 670 connected to the gate driver 660 and configured to amplify the RF power

In this case, an output end of the power amplifier 670 may include a half-bridge transistor circuit or a full-bridge transistor circuit.

In addition, an output end of the power amplifier 670 may include a transistor circuit configured in a SIC or GaN scheme.

In addition, an output end of the power amplifier 670 may include a transistor circuit configured in a Class E series or Class C-E scheme.

If the output end of the power amplifier 670 includes a transistor circuit configured in the Class E series or Class C-E scheme, the DC power supply unit 650 may have a variable voltage output characteristic.

Although the controller 630 described above has been described as calculating the tuning frequency and pulse width of the RF power and controlling the RF signal generator 640 and the DC power supply unit 650, it is not limited or limited thereto, and the controller may also control the reactive circuit 610 as well as the RF signal generator 640 and the DC power supply unit 650.

For example, the controller 630 may control the reactance of the reactive circuit 610 when the matching range is insufficient with only tuning frequency and pulse width control of the RF power of the RF signal generator 640.

For a more specific example, the controller 630 may control the reactance of the reactive circuit 610 such that the reactance components of each of the reactive circuit 610 and the plasma chamber 605 are series-resonant or parallel-resonant at a first frequency to serve as a band pass filter (BPF).

In addition, the matchless plasma source 600 may further include a low pass filter (LPF) or a band pass filter (BPF) (not shown) arranged at an output end of the reactive circuit 610.

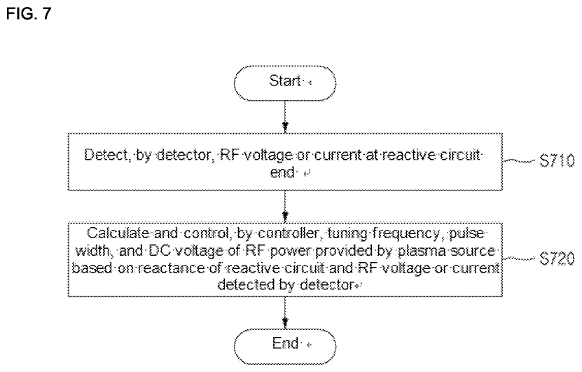

FIG. 7 is a flow chart showing a method of operating a matchless plasma source according to an embodiment.

The operation method described below is based on the assumption that it is performed by the matchless plasma source according to an embodiment of the present invention having the structure described with reference to FIG. 5 and FIG. 6.

Referring to FIG. 7, in step S710, the detector may detect an RF voltage or current at the reactive circuit end (output of the matchless plasma source).

Accordingly, the detected RF voltage or current may be delivered to the controller as a feedback signal.

In step S720, the controller may calculate and control the tuning frequency, pulse width, and DC voltage of the RF power provided by the plasma source based on the reactance of the reactive circuit, and the RF voltage or current detected by the detector.

More specifically, in step S720, the controller may control the RF signal generator further included in the matchless plasma source such that the RF signal generator generates the RF power having the controlled tuning frequency and pulse width.

If the matching range is insufficient only with the tuning frequency and pulse width control of the RF power of the RF signal generator in step S720, the controller may also control the reactance of the reactive circuit.

For example, the controller may control the reactance of the reactive circuit such that the reactance components of each of the reactive circuit and the plasma chamber are series-resonant or parallel-resonant at the first frequency, which is the frequency that the RF power provided by the matchless plasma source has, to serve as the band pass filter.

In addition, in step S720, the controller may control the DC voltage output from the DC power supply unit.

### Mode for Carrying out the Invention

As described above, although embodiments have been described with reference to limited embodiments and drawings, various modifications and variations are possible from the above description to those of ordinary skill in the art. For example, suitable results may be achieved even if the described techniques are performed in an order different from the described method, and/or components of the described system, structure, apparatus, circuit, etc. are coupled or combined in a form different from the described method, or replaced or substituted by other components or equivalents.

Therefore, other implementations, other embodiments, and equivalents to the claims also fall within the scope of the claims described below.

1. A matchless plasma source providing RF power of a first frequency to an electrode of a plasma chamber while being connected to the plasma chamber, the matchless plasma source comprising:
a detector connected to a reactive circuit to detect an RF voltage or current at a reactive circuit end;
the reactive circuit arranged at an output end of the matchless plasma source; and
a controller configured to calculate and control a tuning frequency, a pulse width, and a DC voltage of the RF power provided by the matchless plasma source on the basis of a reactance of the reactive circuit and the RF voltage or current detected by the detector while being connected to the reactive circuit and the detector.

2. The matchless plasma source of claim 1, wherein
the controller is configured to:
control an RF signal generator further comprised in the matchless plasma source such that the RF signal generator generates the RF power having the controlled tuning frequency and pulse width.

3. The matchless plasma source of claim 1, wherein
the controller is configured to:
control a reactance of the reactive circuit such that reactance components of each of the reactive circuit and the plasma chamber are series-resonant or parallel-resonant at the first frequency to serve as a band pass filter (BPF).

4. The matchless plasma source of claim 1, wherein
the matchless plasma source further comprises:
a low pass filter (LPF) or a band pass filter (BPF) arranged at an output end of the reactive circuit.

5. The matchless plasma source of claim 1, wherein
the matchless plasma source further comprises:
an RF signal generator configured to generate the RF power;
a frequency controller configured to adjust a frequency of the RF power under control of the controller;
a pulse width controller configured to adjust a pulse width of the RF power under control of the controller;
a DC power supply configured to supply power to the matchless plasma source;
a gate driver connected to the RF signal generator; and
a power amplifier connected to the gate driver and configured to amplify the RF power.

6. The matchless plasma source of claim 5, wherein
The controller is configured to:
control a DC voltage output from the DC power supply unit.

7. The matchless plasma source of claim 5, wherein
an output end of the power amplifier comprises:
a half-bridge transistor circuit or a full-bridge transistor circuit.

8. The matchless plasma source of claim 5, wherein
an output end of the power amplifier comprises:
a transistor circuit configured in a SIC or GaN scheme.

9. The method of claim 5, wherein
an output end of the power amplifier comprises:
a transistor circuit configured in a Class E series or a Class C-E scheme.

10. The matchless plasma source of claim 9, wherein
the DC power supply unit configured to supply power to the matchless plasma source has:
a variable voltage output characteristic when the output end of the power amplifier comprises the transistor circuit configured in the Class E series or Class C-E scheme.

11. A method of operating a matchless plasma source comprising a reactive circuit arranged at an output end; a detector connected to a front end or a rear end of the reactive circuit; and a controller connected to the reactive circuit and the detector, to provide RF power of a first frequency to an electrode of a plasma chamber while being connected to the plasma chamber, the method comprising:
detecting, by the detector, an RF voltage or current at the reactive circuit end; and
calculating and controlling, by the controller, a tuning frequency, a pulse width, and a DC voltage of the RF power provided by the matchless plasma source on the basis of a reactance of the reactive circuit and the RF voltage or current detected by the detector.

12. The method of claim 11, wherein
the controlling comprises:
controlling an RF signal generator further comprised in the matchless plasma source such that the RF signal generator generates the RF power having the controlled tuning frequency and pulse width.

13. The method of claim 11, wherein
the controlling further comprises:
controlling a reactance of the reactive circuit such that reactance components of each of the reactive circuit and the plasma chamber are in series-resonant or parallel-resonant at the first frequency to serve as a band pass filter (BPF).
